(19) United States
(12) Patent Application Publication
(10) Pub. No.: US 2020/0412305 A1
(43) Pub. Date: Dec. 31, 2020

(54) METHOD AND ARRANGEMENT FOR COMPENSATING MEMORY EFFECTS IN POWER AMPLIFIER

(71) Applicant: Telefonaktiebolaget LM Ericsson (publ), Stockholm (SE)

(72) Inventors: Zhan SHI, Beijing (CN); Jitao NIU, Beijing (CN)

(73) Assignee: Telefonaktiebolaget LM Ericsson (publ), Stockholm (SE)

(21) Appl. No.: 16/971,680

(22) PCT Filed: Mar. 16, 2018
(86) PCT No.: PCT/CN2018/079350

§ 371 Date: Aug. 20, 2020

(51) Int. Cl. H03F 1/32; H03F 3/24

(52) U.S. Cl. CPC H03F 1/3241; H03F 2201/3209; H03F 2200/451; H03F 3/245

(57) ABSTRACT

A method for compensating memory effects in a power amplifier comprises obtaining of an original signal. A variation of power of the original signal with time is determined. The original signal is predistorted for memory effects of the power amplifier into a predistorted signal. The predistorting comprises predistorting of the original signal in dependence of the variation of power. A power amplifier predistortion arrangement for compensating memory effects in a power amplifier, a power amplifier arrangement, and radio transmitter are also disclosed.

### TECHNICAL FIELD

The proposed technology relates in general to methods and arrangements for operation of power amplifiers, and in particular to methods and arrangements for compensating memory effects and nonlinearity in a power amplifier.

### BACKGROUND

With the coming of 5G era, the transmitting signal bandwidth is becoming wider and wider. The memory effect of power amplifiers (PA) becomes very strong because of the wide bandwidth signal. The memory effect concerns that a signal to be amplified also to some extent affects the gain of the power amplifier for signals amplified at a later occasion.

Furthermore, new transistor materials are introduced into PA design to meet the size, efficiency requirement etc. of 4G and 5G. Gallium Nitride (GaN) is one of these popular materials. Unfortunately, an inherent strong memory effect is one of their prominent characters.

Use of a GaN PA with a wide bandwidth signal, which gradually becomes a common case in the 5G era, will result in that the signal distortion after the PA becomes complicated. In other words, the signal is distorted seriously by PA characteristics such as nonlinearity and especially the memory effect. It is generally considered as too complicated to well model or compensate for the distortion by using conventional memory polynomial (MP) or generalized memory polynomial (GMP) models.

Conventionally, power and frequency are regarded as dependency factors of the memory effect in the digital domain. Some compensation models have been built based on this two information respectively, see e.g. [1] T. Ota, H. Ishikawa, and K. Nagatani, “A novel adaptive digital predistortion for wideband power amplifiers with memory effects,” in Proc. Asia-Pacific Microw. Conf. (APMC), vol. 1. December 2015, pp. 1-3, or [2] A. S. Tehrani, T. Eriksson, and C. Fager, “Modeling of long term memory effects in RF power amplifiers with dynamic parameters,” in IEEE MTT-S Int. Microw. Symp. Dig., Montreal, QC, Canada, June 2012, pp. 1-3. Despite these compensation models, memory effects of PA's are still causing distortions of the wide bandwidth signals.

### SUMMARY

In order to better compensate for the PA characteristics distortion, more effective dependency factors of the memory effect are needed. At the same time, such compensations have to be digital resource friendly, i.e. they should not require too large computational resources.

This and other objects are met by embodiments of the proposed technology.

According to a first aspect, there is provided a method for compensating memory effects in a power amplifier. The method comprises obtaining of an original signal. A variation of power of the original signal with time is determined. The original signal is predistorted for memory effects of the power amplifier into a predistorted signal. The predistorting comprises predistorting of the original signal in dependence of the variation of power.

According to a second aspect, there is provided a power amplifier predistortion arrangement for compensating memory effects in a power amplifier. The power amplifier predistortion arrangement is configured to obtain an original signal and to determine a variation of power of the original signal with time. The power amplifier predistortion arrangement is further configured to predistort the original signal for memory effects of the power amplifier into a predistorted signal, whereby the power amplifier predistortion arrangement is configured to predistort the original signal in dependence of the variation of power.

According to a third aspect, there is provided a power amplifier arrangement comprising a power amplifier and a power amplifier predistortion arrangement according to the second aspect. The power amplifier is configured to amplify the predistorted signal into an amplified output signal.

According to a fourth aspect, there is provided a radio transmitter comprising a power amplifier arrangement according to the third aspect and an antenna configured to transmit a radio signal according to the amplified output signal.

According to a fifth aspect, there is provided a computer program comprising instructions, which when executed by at least one processor, cause the at least one processor to obtain an original signal and to determine a variation of power of the original signal with time. The instructions, when executed by the at least one processor, further cause the at least one processor to predistort the original signal for memory effects of the power amplifier into a predistorted signal, wherein the predistortion of the original signal is performed in dependence of the variation of power.

According to a sixth aspect, there is provided a computer-program product comprising a computer-readable medium having stored thereon a computer program of the fifth aspect.

According to a seventh aspect, there is provided a power amplifier predistortion arrangement for compensating memory effects in a power amplifier. The power amplifier predistortion arrangement comprises a signal input for obtain an original signal and a predistorter for predistorting the original signal for memory effects of the power amplifier into a predistorted signal. The predistorter comprises a power differentiator for determining a variation of power of the original signal with time, wherein the predistorter is configured to predistort the original signal in dependence of the variation of power.

According to an eighth aspect, there is provided a power amplifier arrangement comprising a power amplifier predistortion arrangement according to the seventh aspects and a power amplifier. The power amplifier is configured to amplify the predistorted signal into an amplified output signal.

According to a ninth aspect, there is provided a radio transmitter comprising a power amplifier arrangement according to the eighth aspect and an antenna configured to transmit a radio signal according to the amplified output signal.

An advantage of the proposed technology is that new and effective dependency factors of memory effect in digital domain are utilized. Furthermore, a preferred unified compensation structure enables the use of multiple memory effect dependency information. The results show an effectively improved compensation performance on PA characteristics performed in a digital-resource friendly manner.

Other advantages will be appreciated when reading the detailed description.

### BRIEF DESCRIPTION OF THE DRAWINGS

The embodiments, together with further objects and advantages thereof, may best be understood by making reference to the following description taken together with the accompanying drawings, in which:

FIG. 1 is a schematic view of an embodiment of a power amplifier arrangement;

FIG. 2 is a schematic illustration steps of predistortion;

FIG. 3 is a schematic view of an embodiment of a radio transmitter;

FIG. 4 is a schematic view of another embodiment of a power amplifier arrangement;

FIG. 5 is a flow diagram of steps of an embodiment of a method for compensating memory effects in a power amplifier;

FIG. 6 is a diagram illustrating simulation results of different predistortion models;

FIG. 7 is a schematic block diagram illustrating an embodiment of a general compensation model;

FIG. 8 is a diagram illustrating simulation results of other predistortion models; and

FIG. 9 is a diagram illustrating simulation results of yet another predistortion model.

### DETAILED DESCRIPTION

Throughout the drawings, the same reference designations are used for similar or corresponding elements.

For a better understanding of the proposed technology, it may be useful to begin with a brief overview of pre-distortion of power amplifiers.

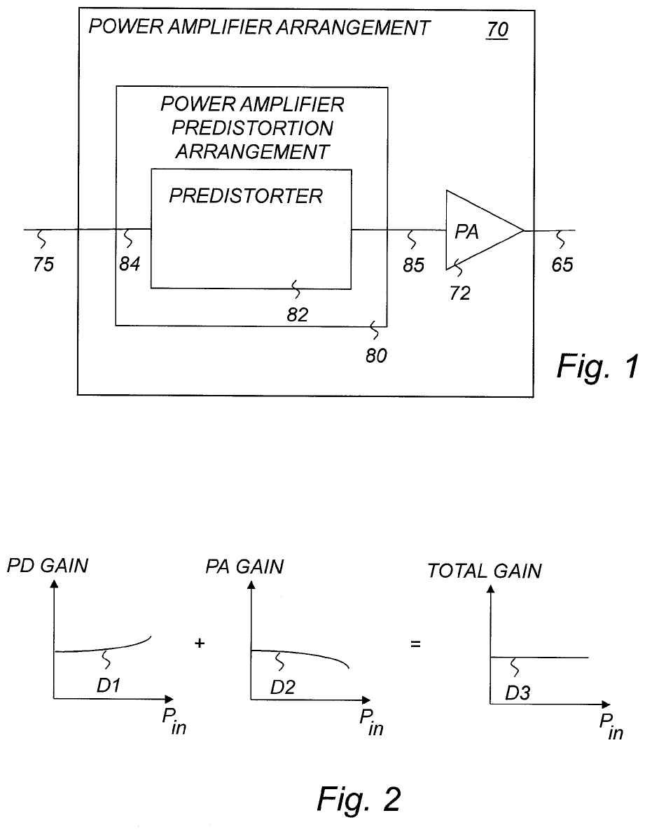

FIG. 1 illustrates an example of a power amplifier arrangement 70. The power amplifier arrangement comprises a power amplifier 72 and a power amplifier predistortion arrangement 80. An original signal 75 is obtained by the power amplifier predistortion arrangement 80 at a signal input 84. The power amplifier predistortion arrangement 80 comprises a predistorter 82 for predistorting said original signal for non-linear characteristics of said power amplifier into a predistorted signal 85. Examples of such distortion characteristics could e.g. be momentary non-linear gain responses and/or memory effects. The predistorted signal 85 is provided to the power amplifier 72, which is configured to amplify the predistorted signal into an amplified output signal 65. An objective for the operation of the predistorter 82 is to achieve an as linear as possible amplified output signal 65.

The operation principle of the predistorter 82 can schematically be illustrated by FIG. 2. The predistorter is given a predistorter gain characteristics according to the diagram D1. The power amplifier has an intrinsic gain characteristics according to the diagram D2. Together, these gains are combined into a total gain, as illustrated in diagram D3. The aim for the predistorter is thus to provide a constant total gain of the amplified output signal with reference to the original signal.

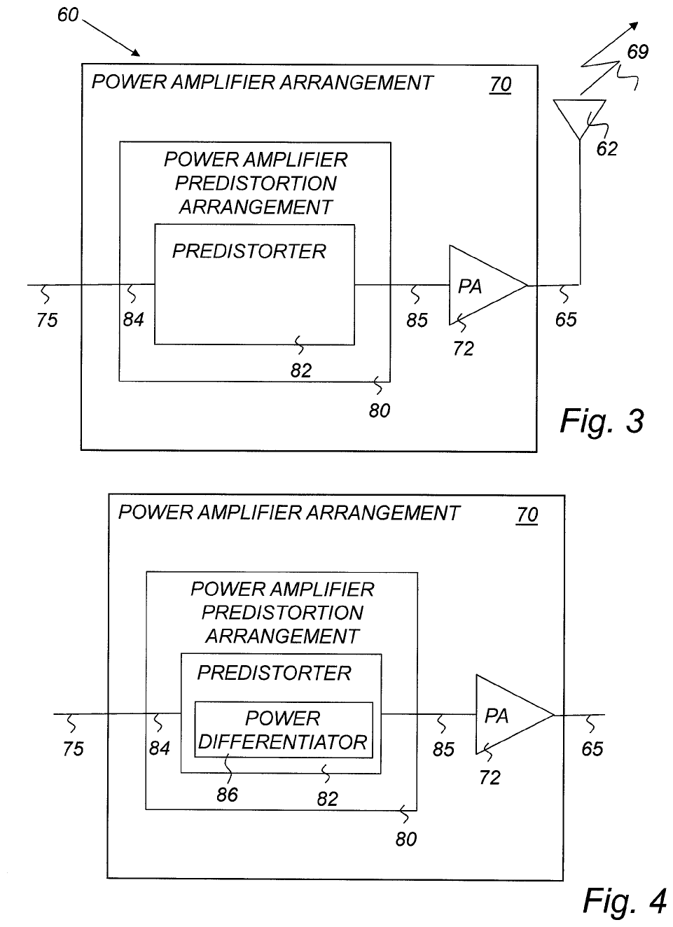

A power amplifier arrangement as in FIG. 1 may be applicable in many different technical contexts. However, one of the more common applications is in radio transmitters, for instance in wireless communication systems. FIG. 3 schematically illustrates such an implementation. An original signal 75 is provided to a radio transmitter 60. The original signal 75 is converted into an amplified output signal 65 by the power amplifier arrangement 70. An antenna 62 is configured to transmit a radio signal 69 according to the amplified output signal 65.

As mentioned in background, memory effects of power amplifiers are causing distortions of the wide bandwidth signals despite the operation of prior art predistortion arrangements. However, it has now been discovered that memory effect is related to not only conventional power and frequency, but also the variation of power with time. In other words, not only the momentary power, or average power of a certain time period, plays a role in the relation to memory effects, but also the prevailing change rate of the power is involved. The derivate of the power is thus of interest.

Therefore, the quantity

$$\frac{dP ( t )}{dt} = Δ P ( t ) = P ( t ) - P ( t - 1 ) , \qquad ( 1 )$$

where t denotes a time slot is also a dependency factor of memory effect. In this relation, P may mean power of an instantaneous original signal, but it could also stand for an average power over a short predetermined period of time.

With reference to FIG. 1, in one embodiment of a power amplifier predistortion arrangement 80 for compensating memory effects in a power amplifier. the power amplifier predistortion arrangement 80 is configured to obtain an original signal 75. The power amplifier predistortion arrangement 80 is furthermore configured to determine a variation of power of the original signal with time. The power amplifier predistortion arrangement 80 is configured to predistort the original signal 75 for memory effects of the power amplifier into a predistorted signal 85, whereby the predistortion of the original signal is performed in dependence of the variation of power.

FIG. 4 illustrates another implementation of an embodiment of a power amplifier predistortion arrangement 80 for compensating memory effects in a power amplifier. The predistorter 82 here comprises a power differentiator 86. The power differentiator 86 is configured for determining a variation of power of the original signal 75 with time. The predistorter 82 is configured to predistort the original signal 75 in dependence of the variation of power into the predistorted signal 85

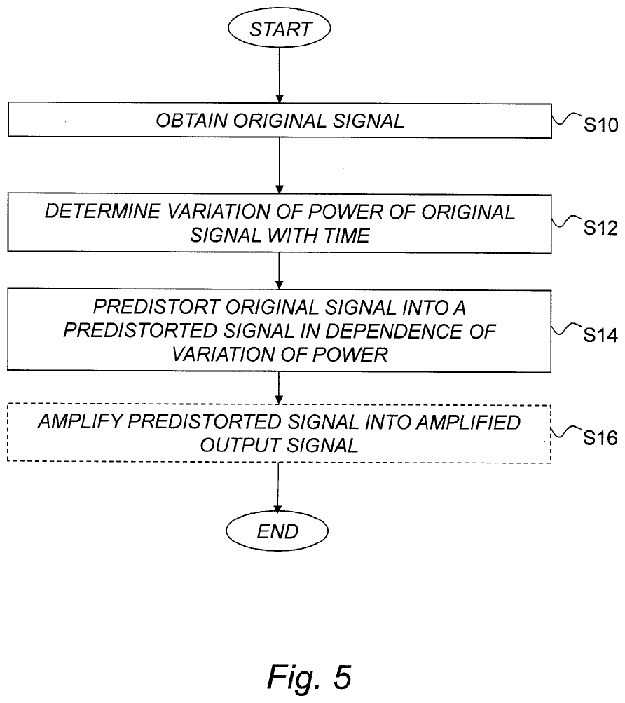

In analogy, FIG. 5 illustrates a flow diagram of steps of a method for compensating memory effects in a power amplifier. In step S10, an original signal is obtained. In step S12, a variation of power of the original signal with time is determined. In step S14, the original signal is predistorted for memory effects of the power amplifier into a predistorted signal. This predistorting is performed by predistorting the original signal in dependence of the variation of power.

In one embodiment, the predistorted signal is further amplified into an amplified output signal, in step S14.

As indicated above, the variation of power does in some aspect reflect the derivate of the power. In one embodiment, the variation of power of the original signal with time is a power measure difference between consecutive time slots. In a particular embodiment, the power measure difference is a difference of instantaneous signal power. In another particular embodiment, the power measure difference is a difference of average signal power. The average signal power is determined over a predetermined period of time.

Simulations have been performed to prove the effectiveness of the above presented ideas. The simulations were performed on a set of real measurement data from power amplifier input and output based on 60 MHz LTE signals. Following models are used to compare the inverse modeling performance. A simulation with an un-predistorted system was made, together with a system with predistortion compensating for momentary non-linear gain responses of the power amplifier according to a Memory Polynomial (MP) approach and a system utilizing predistortion in dependence of the variation of power as a complement to the MP approach.

The Normalized Mean Square Error (NMSE) was compared for these different models. It was found that the conventional MP approach reached an NMSE of −36.23 dB and the approach using predistortion in dependence of the variation of power reached a level of −42.40 dB.

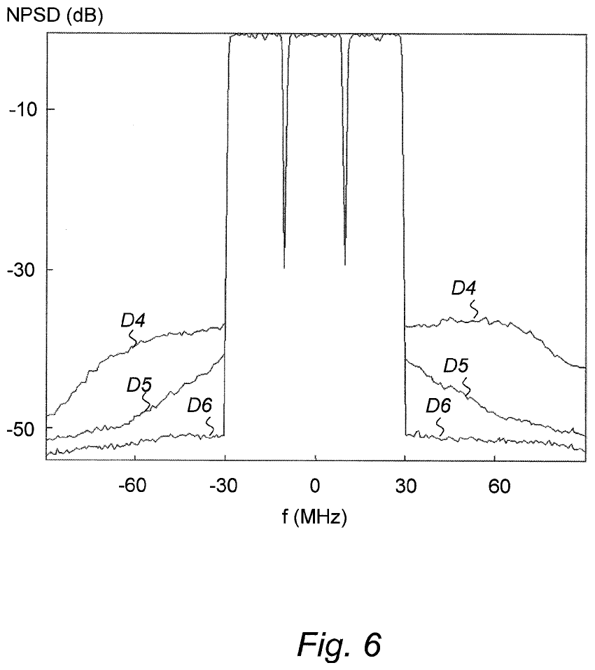

A comparison of Adjacent Channel Leakage Ratio (ACLR) of the different models was also performed. The results are schematically illustrated in FIG. 6. Curve D4 corresponds to the un-predistorted power amplifier, curve D5 corresponds to the predistortion using a conventional MP approach and curve D6 corresponds to the approach using predistortion in dependence of the variation of power.

The prior art compensations for memory effect dependencies have been performed as a mono-factor approach. However, in order to improve the compensation performance further, it is preferred to utilize different memory effect factors jointly and effectively.

In one embodiment, the method for compensating memory effects in a power amplifier comprises the further step of determining an additional memory effect dependency factor from the original signal. The step of predistorting consequently comprises predistorting the original signal in further dependence of the additional memory effect dependency factor.

To this end, a compensation model for memory effect and nonlinearity is proposed to be expressed as follow:

y(t)=α₀X₀(t)+Σₖ₌₁^{K}αₖΠₘ₌₁^{M(k)}δ_{m,k}(t)Xₖ(t), (2)

where δ_{m,k} means memory effect dependency factors. These memory effect dependency factors include the variation of power but may additionally include dependencies of conventional power and/or frequency and/or other types of dependency factors. Xₖ(t) stands for a vector of a power amplifier behavioral model structure. Non-exclusive examples of such models are MP, and Generalized MP (GMP). αₖ are corresponding coefficients vector of the model. Each Xₖ(t) could be same or different, depending on the nature of the dependency factor involved and resources and performance tradeoff. k corresponds to a particular kind of dependency factor. M is an integer and defines the number of dependency factors of each kind. Furthermore, M might be a function of k.

In a particular embodiment, one of the memory effect dependency factors is dependent on the variation of power of said original signal.

A vector of a power amplifier behavioral model is extracted and summarized based on the power amplifier basic physical character and on experiment. This model is thus a kind of description of the responses of the power amplifier. The Different power amplifies behavioral model focus on different aspects such as accuracy or numerical stability. In other words, different power amplifier behavioral models may be chosen to balance the performance and complexity. As mentioned above different Xₖ(t) could be employed for different dependency factors in order to emphasize different aspects. However, as was utilized in the above simulations, the X₀(t)=X₁(t)= . . . =Xₖ(t)=X(t) may be selected to be the same.

In one particular example, the vector of the power amplifier behavioral model structure could be selected as:

$${X}_{k} ( t ) = [ x ( t ) , x ( t ) {\vert x ( t ) \vert}^{2} , … , x ( t ) {\vert x ( t ) \vert}^{2 L} , \\ … … , \\ x ( t - Q ) , x ( t - Q ) {\vert x ( t - Q ) \vert}^{2} , … , x ( t - Q ) {\vert x ( t - Q ) \vert}^{2 L} ] . \qquad ( 3 )$$

Q denotes the memory length and L stands for nonlinearity order. Both these parameters affect the structure, the number of items and thereby complexity. This approach is a common model in the predistortion field, and was used in the above simulations to demonstrate the robustness of our method. A memory polynomial with memory length (Q) of 4 and nonlinearity order (2L+1) of 11 was utilized as X(t) in that particular simulation.

In another particular example, the vector of the power amplifier behavioral model structure could be selected as:

$${X}_{k} ( t ) = [ x ( t ) , x ( t ) \vert x ( t ) \vert , … , x ( t ) {\vert x ( t ) \vert}^{L} , \\ … … , \\ x ( t - Q ) , x ( t - Q ) \vert x ( t - Q ) \vert , … , x ( t - Q ) {\vert x ( t - Q ) \vert}^{L} ] \qquad ( 4 )$$

Many other types of power amplifier behavioral models are also used in this field and can be applied in the present model.

As mentioned above, αₖ stands for the coefficients of model. It is a vector and corresponds to the items in the vector Xₖ(t). There are many adaptive algorithms in the prior art field of predistortion to estimate these coefficients and its core is to compare and process the original signal, the predistorted signal and the amplified output signal to generate αₖ. It can be noted that αₖ does not include any memory effect information and cannot therefore be combined into the same factors as the memory effect dependency.

In one particular embodiment, the predistorted signal, y(t), is determined as:

y(t)=α₀X₀(t)+α₃δ₃(t)X₃(t), (5)

where Xₖ(t), k=0, 3, is a vector of a power amplifier behavioural model structure, αₖ, k=0, 3, are corresponding coefficients of said power amplifier behavioural model structure and δ₃ is a dependency factor being dependent on said variation of power of said original signal.

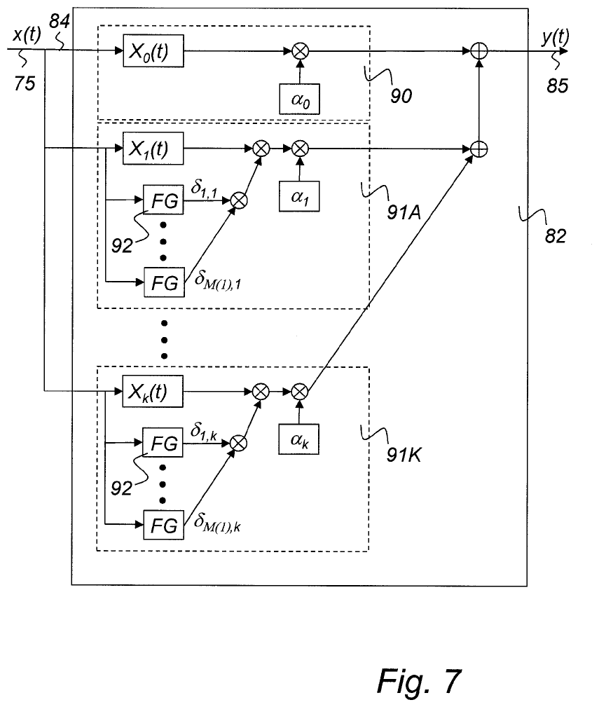

The above presented general compensation model can also be illustrated as a model structure, as schematically shown in FIG. 7. From this schematics, the model structure can be understood in detail. An original signal 75, x(t), is received in a predistorter 82 on the signal input 84. A vector of a power amplifier behavioral model X₀(t) is created in a non-linearity section 90 based on the original signal and is multiplied with the corresponding coefficient vector α₀. This gives basically a correction of the momentary non-linear gain responses of the power amplifier. The original signal 75 is also provided to a number of memory effect sections 91A-K. In each section, a power amplifier behavioral model Xₖ(t), which may be the same or different, is used. In each memory effect section 91A, the original signal 75 is further provided to one or more factor generators 92. Each of these factor generators 92 are targeting a particular memory effect dependency and generates a factor of memory effect dependency based on at least the latest original signal 75. In each memory effect section 91, the factors of memory effect dependency are multiplied together to form a total section factor and is then multiplied with the power amplifier behavioral model Xₖ(t) and also multiplied with the corresponding coefficient vector αₖ. The outputs from all sections 90, 91A-K are summed together into the predistorted signal 85, y(t).

In the particular embodiment presented by the relation (5) here above, the predistorter 82 comprises one memory effect section 91A with one factor generator. This factor generator can thus be considered as constituting a power differentiator for determining a variation of power of said original signal with time.

However, the general compensation model opens up for using more than one dependency factor for the power amplifier memory effects.

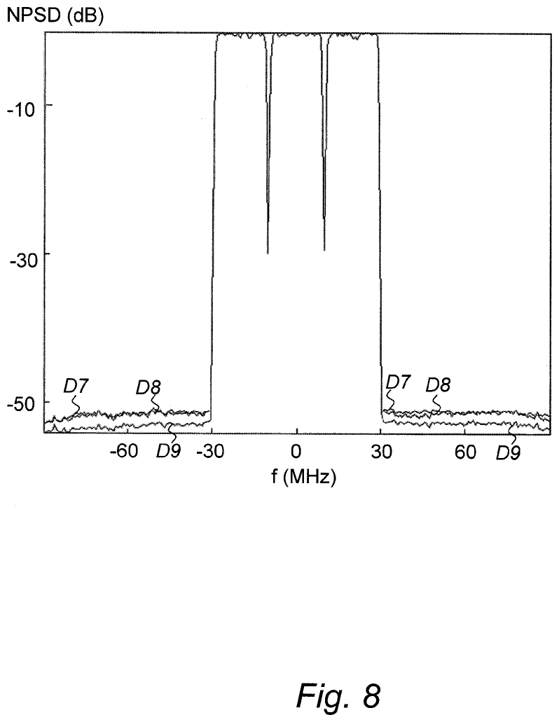

In FIG. 8, further simulation results are illustrated. Curve D7 corresponds to an approach using predistortion in dependence of the mean power. Curve D8 corresponds to an approach using predistortion in dependence of the frequency. These approaches correspond to NMSE of −42.02 dB and −41.68, respectively. A memory polynomial with memory length of 4 and nonlinearity order of 11 is used as X(t) as in previous simulations. NMSE and ACLR performance are improved greatly by using each memory effect dependency factor respectively comparing with conventional MP (a). From the point of view of NMSE, the new factor based on the variation of power (FIG. 6) achieves a slightly better performance comparing with conventional factors of curves D7 and D8.

However, an even better result can be achieved if more than one memory effect dependency is used. Curve D9 illustrates a simulation, where predistortion in dependence of the mean power, in dependence of the frequency and in dependence of the variation of power. A NMSE of −43.12 dB was achieved.

In a particular embodiment, the method for compensating memory effects in a power amplifier comprises the further step of determining a mean power over a predetermined period of time of the original signal and a frequency of the original signal. The predistorting then comprises predistorting of the original signal in further dependence of the mean power and of said frequency.

One particular embodiment can be described in terms of an equation. A predistorted signal, y(t), is then determined as:

y(t)=α₀X₀(t)+α₁δ₁(t)X₁(t)+α₂δ₂(t)X₂(t)+α₃δ₃(t)X₃(t). (6)

In this relation, Xₖ(t), k=0, 1, 2, 3, is a vector of a power amplifier behavioural model structure, αₖ, k=0, 1, 2, 3, are corresponding coefficients of said power amplifier behavioural model structure, δ₁ is a dependency factor being dependent on the mean power of the original signal, δ₂ is a dependency factor being dependent on the frequency of the original signal and δ₃ is a dependency factor being dependent on the variation of power of the original signal.

The NMSE and ACLR performance are improved more by using these factors jointly.

Further dependency factors may also be utilized in an analogous manner according to the general compensation model (2), presented above.

A minor disadvantage with the use of multiple dependency factors is that addition of the individual correction results requires relatively large computational effort. In other words, multi-factor compensation will cost large digital resources. This corresponds to a situation in equation (2) having a large k.

However, some memory effect dependency factors have been found to have a low correlation. This opens up for sharing one common model using multiplication and save digital resources. In equation (2), this corresponds to cases where M is larger than 1. In such a way, the parameter k can be reduced while maintaining the same total number of dependency factors.

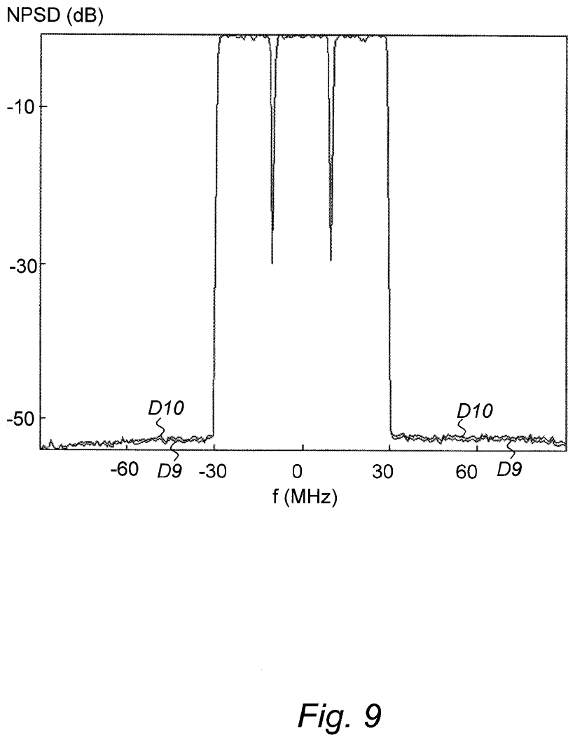

A simulation has been performed on a resource-friendly system where the dependency factors of the mean power of the original signal and of the frequency share the same model. The result is shown in FIG. 9. Curve D9 is the same as presented in FIG. 6, while curve D10 corresponds to the resource-friendly approach. The NMSE corresponding to the curve D10 is −42.94 dB, which is very close indeed to the optimum multi-factor compensation of curve D6. However, the computational complexity is reduced considerably.

In a particular embodiment, the predistorted signal, y(t), is determined as:

y(t)=α₀X₀(t)+α₁δ₁(t)δ₂(t)X₁(t)+α₃δ₃(t)X₃(t), (7)

where Xₖ(t), k=0, 1, 3, is a vector of a power amplifier behavioural model structure, αₖ, k=0, 1, 3, are corresponding coefficients of the power amplifier behavioural model structure, δ₁ is a dependency factor being dependent on the mean power of the original signal, δ₂ is a dependency factor being dependent on the frequency of the original signal and δ₃ is a dependency factor being dependent on the variation of power of the original signal.

As mentioned above, a power amplifier predistortion arrangement or a power amplifier arrangement according to the ideas presented above can be utilized in different kinds of radio transmitters. The radio transmitters may constitute parts of different kinds of wireless communication devices and radio communication network nodes.

As used herein, the non-limiting terms “User Equipment (UE)”, “station (STA)” and “wireless communication device” or “wireless device” may refer to a mobile phone, a cellular phone, a Personal Digital Assistant (PDA) equipped with radio communication capabilities, a smart phone, a laptop or Personal Computer (PC) equipped with an internal or external mobile broadband modem, a tablet PC with radio communication capabilities, a target device, a device to device UE, a machine type UE or UE capable of machine to machine communication, iPAD, Customer Premises Equipment (CPE), Laptop Embedded Equipment (LEE), Laptop Mounted Equipment (LME), Universal Serial Bus (USB) dongle, a portable electronic radio communication device, a sensor device equipped with radio communication capabilities or the like. In particular, the term “UE”, the term “Station”, the term “wireless device” and the term “wireless communication device” should be interpreted as non-limiting terms comprising any type of wireless device communicating with a network node in a wireless communication system and/or possibly communicating directly with another wireless communication device. In other words, a wireless communication device may be any device equipped with circuitry for wireless communication according to any relevant standard for communication.

As used herein, the non-limiting term “network node” may refer to base stations, access points, network control nodes such as network controllers, radio network controllers, base station controllers, access controllers, and the like. In particular, the term “base station” may encompass different types of radio base stations including standardized base stations such as Node Bs (NB), or evolved Node Bs (eNB) and also macro/micro/pico radio base stations, home base stations, also known as femto base stations, relay nodes, repeaters, radio access points, Base Transceiver Stations (BTS), and even radio control nodes controlling one or more Remote Radio Units (RRU), or the like.

The general non-limiting term “communication unit” includes network nodes and/or associated wireless devices.

As used herein, the term “network device” may refer to any device located in connection with a communication network, including but not limited to devices in access networks, core networks and similar network structures. The term network device may also encompass cloud-based network devices.

It will be appreciated that the methods and devices described herein can be combined and re-arranged in a variety of ways.

For example, embodiments may be implemented in hardware, or in software for execution by suitable processing circuitry, or a combination thereof.

The steps, functions, procedures, modules and/or blocks described herein may be implemented in hardware using any conventional technology, such as discrete circuit or integrated circuit technology, including both general-purpose electronic circuitry and application-specific circuitry.

Alternatively, or as a complement, at least some of the steps, functions, procedures, modules and/or blocks described herein may be implemented in software such as a computer program for execution by suitable processing circuitry such as one or more processors or processing units.

Examples of processing circuitry includes, but is not limited to, one or more microprocessors, one or more Digital Signal Processors (DSPs), one or more Central Processing Units (CPUs), video acceleration hardware, and/or any suitable programmable logic circuitry such as one or more Field Programmable Gate Arrays (FPGAs), or one or more Programmable Logic Controllers (PLCs).

It should also be understood that it may be possible to re-use the general processing capabilities of any conventional device or unit in which the proposed technology is implemented. It may also be possible to re-use existing software, e.g. by reprogramming of the existing software or by adding new software components.

According to an aspect of the proposed technology there is provided a power amplifier predistortion arrangement configured to obtain an original signal, to determine a variation of power of the original signal with time and to predistort the original signal for memory effects of the power amplifier into a predistorted signal. The power amplifier predistortion arrangement is configured to predistort the original signal in dependence of the variation of power.

In one embodiment, the power amplifier predistortion arrangement is based on a processor-memory implementation according to an embodiment. In this particular example, the power amplifier predistortion arrangement comprises a processor and a memory, the memory comprising instructions executable by the processor, whereby the processor is operative to obtain an original signal, to determine a variation of power of the original signal with time and to predistort the original signal for memory effects of the power amplifier into a predistorted signal.

In another embodiment, the power amplifier predistortion arrangement is based on a hardware circuitry implementation. Particular examples of suitable hardware (HW) circuitry include one or more suitably configured or possibly reconfigurable electronic circuitry, e.g. Application Specific Integrated Circuits (ASICs), Field Programmable Gate Arrays (FPGAs), or any other hardware logic such as circuits based on discrete logic gates and/or flip-flops interconnected to perform specialized functions in connection with suitable registers (REG), and/or memory units (MEM).

In another embodiment, the power amplifier predistortion arrangement is based on combination of both processor(s) and hardware circuitry in connection with suitable memory unit(s)

Alternatively, or as a complement, at least some of the steps, functions, procedures, modules and/or blocks described herein may be implemented in software such as a computer program for execution by suitable processing circuitry such as one or more processors or processing units.

The flow diagram or diagrams presented herein may therefore be regarded as a computer flow diagram or diagrams, when performed by one or more processors. A corresponding apparatus may be defined as a group of function modules, where each step performed by the processor corresponds to a function module. In this case, the function modules are implemented as a computer program running on the processor.

Examples of processing circuitry includes, but is not limited to, one or more microprocessors, one or more Digital Signal Processors (DSPs), one or more Central Processing Units (CPUs), video acceleration hardware, and/or any suitable programmable logic circuitry such as one or more Field Programmable Gate Arrays (FPGAs), or one or more Programmable Logic Controllers (PLCs).

It should also be understood that it may be possible to re-use the general processing capabilities of any conventional device or unit in which the proposed technology is implemented. It may also be possible to re-use existing software, e.g. by reprogramming of the existing software or by adding new software components.

In a particular embodiment, a computer program comprises instructions, which when executed by at least one processor, cause the at least one processor to obtain an original signal, to determine a variation of power of the original signal with time and to predistort the original signal for memory effects of the power amplifier into a predistorted signal. The instructions, when executed by the at least one processor, cause the at least one processor to predistort the original signal in dependence of the variation of power.

The proposed technology also provides a carrier comprising the computer program, wherein the carrier is one of an electronic signal, an optical signal, an electromagnetic signal, a magnetic signal, an electric signal, a radio signal, a microwave signal, or a computer-readable storage medium.

By way of example, the software or computer program may be realized as a computer program product, which is normally carried or stored on a computer-readable medium in particular a non-volatile medium. The computer-readable medium may include one or more removable or non-removable memory devices including, but not limited to a Read-Only Memory (ROM), a Random Access Memory (RAM), a Compact Disc (CD), a Digital Versatile Disc (DVD), a Blu-ray disc, a Universal Serial Bus (USB) memory, a Hard Disk Drive (HDD) storage device, a flash memory, a magnetic tape, or any other conventional memory device. The computer program may thus be loaded into the operating memory of a computer or equivalent processing device for execution by the processing circuitry thereof.

The flow diagram or diagrams presented herein may be regarded as a computer flow diagram or diagrams, when performed by one or more processors. A corresponding apparatus may be defined as a group of function modules, where each step performed by the processor corresponds to a function module. In this case, the function modules are implemented as a computer program running on the processor.

The computer program residing in memory may thus be organized as appropriate function modules configured to perform, when executed by the processor, at least part of the steps and/or tasks described herein.

In one embodiment, a power amplifier predistortion arrangement for compensating memory effects in a power amplifier, comprises a signal input for obtain an original signal. The power amplifier predistortion arrangement further comprises a predistorter for predistorting the original signal for memory effects of the power amplifier into a predistorted signal. The predistorter comprises a power differentiator for determining a variation of power of the original signal with time. The predistorter is configured to predistort the original signal in dependence of the variation of power.

In the above description, it has been shown that the introduction of a new factor of compensation for memory effect based on power variations leads to improved results. Furthermore, by utilizing a proposed compensation structure of using memory effect dependency factors jointly, the result can be improved even more. Only slightly decreased performance is obtained if the compensation structure is simplify based on low correlation between factors.

The embodiments described above are merely given as examples, and it should be understood that the proposed technology is not limited thereto. It will be understood by those skilled in the art that various modifications, combinations and changes may be made to the embodiments without departing from the present scope as defined by the appended claims. In particular, different part solutions in the different embodiments can be combined in other configurations, where technically possible.

### ABBREVIATIONS

ACLR Adjacent Channel Leakage Ratio
ASIC Application Specific Integrated Circuits
BTS Base Transceiver Stations
CD Compact Disc
CPE Customer Premises Equipment
CPU Central Processing Units
DSP Digital Signal Processors
DVD Digital Versatile Disc
eNB evolved Node B
FPGA Field Programmable Gate Arrays
GaN Gallium Nitride
GMP General memory polynomial
HDD Hard Disk Drive
HW hardware
I/O input/output
LEE Laptop Embedded Equipment
LME Laptop Mounted Equipment
MEM memory units
MP Memory polynomial
NB Node B
ND Network Device
NMSE Normalized mean square error
PA Power Amplifier
PC Personal Computer
PDA Personal Digital Assistant
PLC Programmable Logic Controllers
RAM Random Access Memory
REG registers
ROM Read-Only Memory
RRU Remote Radio Units
STA Station
SW software
UE User Equipment
USB Universal Serial Bus

### REFERENCES

[1] T. Ota, H. Ishikawa, and K. Nagatani, “A novel adaptive digital predistortion for wideband power amplifiers with memory effects,” in Proc. Asia-Pacific Microw. Conf. (APMC), vol. 1. December 2015, pp. 1-3.

[2] A. S. Tehrani, T. Eriksson, and C. Fager, “Modeling of long term memory effects in RF power amplifiers with dynamic parameters,” in IEEE MTT-S Int. Microw. Symp. Dig., Montreal, QC, Canada, June 2012, pp. 1-3.

1. A method for compensating memory effects in a power amplifier comprising:
obtaining an original signal; and
predistorting said original signal for memory effects of said power amplifier into a predistorted signal by
determining a variation of power of said original signal with time,
wherein the predistorting comprises predistorting said original signal in dependence of said variation of power to generate a predistorted signal y(t).

2. The method according to claim 1, further comprising:
amplifying said predistorted signal into an amplified output signal.

3. The method according to claim 1, wherein said variation of power of said original signal with time is a power measure difference between consecutive time slots.

4. The method according to claim 3, wherein said power measure difference is a difference of instantaneous signal power.

5. The method according to claim 3, wherein said power measure difference is a difference of average signal power, said average signal power being determined over a predetermined period of time.

6. The method according to claim 1, wherein said predistorted signal y(t) is determined as:
y(t)=α₀X₀(t)+α₃δ₃(t)X₃(t),
where Xₖ(t), k=0, 3, is a vector of a power amplifier behavioural model structure αₖ, k=0, 3, are corresponding coefficients of said power amplifier behavioural model structure and δ₃ is a dependency factor being dependent on said variation of power of said original signal.

7. The method according to claim 1 further comprising:
determining an additional memory effect dependency factor from said original signal,
wherein the predistorting comprises predistorting said original signal in further dependence of said additional memory effect dependency factor.

8. The method according to claim 1, wherein said predistorted signal y(t) is determined as:
y(t)=α₀X₀(t)+Σₖ₌₁^{K}αₖΠₘ₌₁^{M(k)}δ_{m,k}(t)Xₖ(t),
where Xₖ(t), k=0, K, is a vector of a power amplifier behavioural model structure αₖ, k=0, K, are corresponding coefficients of said power amplifier behavioural model structure and δ_{m,k} are dependency factors, of which one is dependent on said variation of power of said original signal.

9. The method according to claim 1 further comprising:
determining a mean power over a predetermined period of time of said original signal and a frequency of said original signal,
wherein the predistorting comprises predistorting said original signal in further dependence of said mean power and of said frequency.

10. The method according to claim 9, wherein said predistorted signal y(t) is determined as:
y(t)=α₀X₀(t)+α₁δ₁(t)X₁(t)+α₂δ₂(t)X₂(t)+α₃δ₃(t)X₃(t),
where Xₖ(t), k=0, 1, 2, 3, is a vector of a power amplifier behavioural model structure αₖ, k=0, 1, 2, 3, are corresponding coefficients of said power amplifier behavioural model structure, δ₁ is a dependency factor being dependent on said mean power of said original signal, δ₂ is a dependency factor being dependent on said frequency of said original signal and δ₃ is a dependency factor being dependent on said variation of power of said original signal.

11. The method according to claim 9, wherein said predistorted signal, y(t) is determined as:
y(t)=α₀X₀(t)+α₁δ₁(t)δ₂(t)X₁(t)+α₃δ₃(t)X₃(t),
where Xₖ(t), k=0, 1, 3, is a vector of a power amplifier behavioural model structure αₖ, k=0, 1, 3, are corresponding coefficients of said power amplifier behavioural model structure, δ₁ is a dependency factor being dependent on said mean power of said original signal, δ₂ is a dependency factor being dependent on said frequency of said original signal and δ₃ is a dependency factor being dependent on said variation of power of said original signal.

12. A power amplifier predistorter for compensating memory effects in a power amplifier, comprising:
a processor; and
a memory containing instructions which, when executed by the processor, cause the power amplifier predistorter to:
obtain an original signal; and
predistort said original signal for memory effects of said power amplifier into a predistorted signal, by performing operations
to determine a variation of power of said original signal with time and
predistort said original signal in dependence of said variation of power to generate a predistorted signal.

13. (canceled)

14. The power amplifier predistorter of claim 12, wherein the power amplifier predistorter is coupled to a power amplifier and
wherein said power amplifier is configured to amplify said predistorted signal into an amplified output signal.

15. The power amplifier predistorter of claim 14, wherein the power amplifier is coupled to
an antenna configured to transmit a radio signal according to said amplified output signal.

16. A non-transitory computer-readable storage medium comprising instructions which, when executed by at least one processor, cause a predistorter for compensating memory effects in a power amplifier to perform operations comprising:
obtaining an original signal; and
predistorting said original signal for memory effects of a power amplifier into a predistorted signal by determining a variation of power of said original signal with time and predistorting said original signal in dependence of said variation of power to generate a predistorted signal.

17-20. (canceled)
